(19) United States
(12) Patent Application Publication
(10) Pub. No.: US 2016/0197199 A1
(43) Pub. Date: Jul. 7, 2016

(54) SEMICONDUCTOR DEVICE

(71) Applicant: Sharp Kabushiki Kaisha, Osaka (JP)

(72) Inventors: Shingo KAWASHIMA, Osaka-shi (JP); Yukinobu NAKATA, Osaka-shi (JP); Atsuhito MURAI, Osaka-shi (JP); Shinya TANAKA, Osaka-shi (JP)

(21) Appl. No.: 15/067,771

(22) Filed: Mar. 11, 2016

Related U.S. Application Data
(62) Division of application No. 13/979,478, filed on Sep. 24, 2013.

(30) Foreign Application Priority Data
Jan. 13, 2011 (JP) 2011-004475

(51) Int. Cl. H01L 29/786; H01L 29/24

(52) U.S. Cl. CPC H01L 29/78693; H01L 29/78696; H01L 29/78606; H01L 29/247

(57) ABSTRACT

A semiconductor device includes an oxide semiconductor layer including a first contact region and a second contact region and a channel region located between the first contact region and the second contact region; a source electrode provided on the oxide semiconductor layer so as to be in contact with the first contact region; and a drain electrode provided on the oxide semiconductor layer so as to be in contact with the second contact region. All side faces of the oxide semiconductor layer are located over the gate electrode; a width of the source electrode is greater than a width of the oxide semiconductor layer; and a width of the drain electrode is greater than a width of the oxide semiconductor layer.

### TECHNICAL FIELD

The present invention relates to a semiconductor device including a thin film transistor (TFT) having an oxide semiconductor layer.

### BACKGROUND ART

In recent years, vigorous development activities are being directed toward TFTs with an oxide semiconductor layer containing In (indium), Zn (zinc), Ga (gallium), or the like (e.g. Patent Documents 1 to 4). A TFT with an oxide semiconductor layer (hereinafter referred to as an oxide semiconductor TFT) has a high mobility and high ON-OFF ratio characteristics.

Patent Document 4 discloses a semiconductor device in which a light shielding film or the like is formed to prevent shorter-wavelength visible light from striking an amorphous oxide semiconductor (a-IGZO) layer containing In, Ga, and Zn. By forming a light shielding film, changes in the characteristics of the oxide semiconductor TFT are prevented.

### CITATION LIST

### Patent Literature

[Patent Document 1] Japanese Laid-Open Patent Publication No. 2010-98305

[Patent Document 2] Japanese Laid-Open Patent Publication No. 2009-224354

[Patent Document 3] Japanese Laid-Open Patent Publication No. 2007-150157

[Patent Document 4] Japanese Laid-Open Patent Publication No. 2007-115902

### SUMMARY OF INVENTION

### Technical Problem

However, the semiconductor device fabrication disclosed in Patent Document 4 has a problem in that more steps are needed for forming the light shielding film. On the other hand, in the construction disclosed in Patent Document 4, a light shielding film is formed only on the backlight side of the TFT, so that this light shielding film cannot block any light entering oxide semiconductor TFT from the viewer's side; thus, shorter-wavelength visible light may strike the oxide semiconductor TFT. If any more light shielding film were to be formed so as to block light entering the oxide semiconductor TFT from the viewer's side, the number of production steps would be further increased.

The present invention has been made in view of the above problems, and an objective thereof is to provide a semiconductor device which can be produced without increasing the number of production steps and whose TFT characteristics are unlikely to be affected by light.

### Solution to Problem

A semiconductor device according to an embodiment of the present invention includes: a substrate; a gate electrode formed on the substrate; a gate insulating layer formed on the gate electrode; an island-shaped oxide semiconductor layer formed on the gate insulating layer, the oxide semiconductor layer having a first contact region and a second contact region and a channel region located between the first contact region and the second contact region; a source electrode formed on the oxide semiconductor layer so as to be in contact with the first contact region; and a drain electrode formed on the oxide semiconductor layer so as to be in contact with the second contact region, wherein, all side faces of the oxide semiconductor layer are located over the gate electrode; in a cross section which is perpendicular to the substrate and traverses the first contact region in a channel width direction, a width of the source electrode is greater than a width of the oxide semiconductor layer; and in a cross section which is perpendicular to the substrate and traverses the second contact region in the channel width direction, a width of the drain electrode is greater than a width of the oxide semiconductor layer.

In one embodiment, within a surface of the oxide semiconductor layer, the first contact region and side faces of the first contact region relative to the channel width direction are covered by the source electrode; and within the surface of the oxide semiconductor layer, the second contact region and side faces of the second contact region relative to the channel width direction are covered by the drain electrode.

In one embodiment, within a surface of the oxide semiconductor layer, all upper face and side faces except an upper face of the channel region and side faces of the channel region relative to the channel width direction are covered by the source electrode or the drain electrode.

In one embodiment, within a surface of the oxide semiconductor layer, an upper face of the channel region and side faces of the channel region relative to the channel width direction are covered by an oxygen-containing insulative film and are in contact with the oxygen-containing insulative film; and when viewed from a normal direction of the substrate, a portion of the oxide semiconductor layer that is not covered by the source electrode or the drain electrode has a first recessed portion or a first cutaway portion.

A semiconductor device according to another embodiment of the present invention includes: a substrate; a gate electrode formed on the substrate; a gate insulating layer formed on the gate electrode; an island-shaped oxide semiconductor layer formed on the gate insulating layer, the oxide semiconductor layer having a first contact region and a second contact region and a channel region located between the first contact region and the second contact region; a source electrode formed on the oxide semiconductor layer so as to be in contact with the first contact region; and a drain electrode formed on the oxide semiconductor layer so as to be in contact with the second contact region, wherein, all side faces of the oxide semiconductor layer are located over the gate electrode; regions of the oxide semiconductor layer other than a surface and side faces of the channel region are covered by the source electrode and the drain electrode, a region of the oxide semiconductor layer which is not covered by the source electrode or the drain electrode is covered by an oxygen-containing insulative film and is in contact with the oxygen-containing insulative film, when viewed from a normal direction of the substrate, a portion of the oxide semiconductor layer which is not covered by the source electrode or the drain electrode has a first recessed portion or a first cutaway portion.

In one embodiment, when viewed from the normal direction of the substrate, given a distance L between the source electrode and the drain electrode sandwiching the side faces of the channel region, a length of the first recessed portion or the first cutaway portion along the channel length direction and a length of the first recessed portion or the first cutaway portion along the channel width direction are, each independently, greater than 0 but equal to or less than L/2.

In one embodiment, the oxygen-containing insulative film is made of SiO₂.

In one embodiment, when viewed from a normal direction of the substrate, the source electrode has a recessed portion, and the drain electrode is within the recessed portion.

In one embodiment, there is a plurality of first contact regions and second contact regions.

In one embodiment, the oxide semiconductor layer contains In, Ga, and Zn.

### Advantageous Effects of Invention

According to the present invention, a semiconductor device which can be produced without increasing the number of production steps and whose TFT characteristics are unlikely to be affected by light is provided.

### BRIEF DESCRIPTION OF DRAWINGS

FIG. 1 (a) is a schematic plan view of a semiconductor device 100A according to an embodiment of the present invention; and (b) is a schematic cross-sectional view of the semiconductor device 100A along line I-I′ in (a).

FIG. 2 (a) is a graph showing gate voltage (Vg)-drain current (Id) characteristics of an oxide semiconductor TFT described in Patent Document 4; and (b) is a graph showing gate voltage (Vg)-drain current (Id) characteristics of a TFT 10A.

FIG. 3 (a) is a schematic plan view of a semiconductor device 100B according to another embodiment of the present invention; and (b) is a schematic plan view of a semiconductor device 100B′.

FIG. 4 A graph showing gate voltage (Vg)-drain current (Id) characteristics of a TFT 10B.

FIG. 5 (a) is a schematic plan view of a semiconductor device 100C according to still another embodiment of the present invention; and (b) is a schematic cross-sectional view of the semiconductor device 100C along line II-II′ in (a).

FIG. 6 A graph showing gate voltage (Vg)-drain current (Id) characteristics of a TFT 10C.

FIG. 7 (a) is a schematic plan view of a semiconductor device 100D according to still another embodiment of the present invention; and (b) is a schematic cross-sectional view of the semiconductor device 100D along line III-III′ in (a).

FIG. 8 (a) is a schematic plan view of a gate terminal 90A included in a semiconductor device according to an embodiment of the present invention; (b) is a schematic plan view of a source terminal 90B included in a semiconductor device according to an embodiment of the present invention; (c) is a schematic cross-sectional view of the gate terminal 90A along line A1-A1′ in (a); and (d) is a schematic cross-sectional view of the source terminal 90B along line A2-A2′ in (b).

### DESCRIPTION OF EMBODIMENTS

With reference to the drawings, a semiconductor device (TFT substrate) according to an embodiment of the present invention will be described. A semiconductor device according to the present embodiment is a semiconductor device for use in a liquid crystal display device, for example. However, the present invention is not limited to the illustrated embodiment.

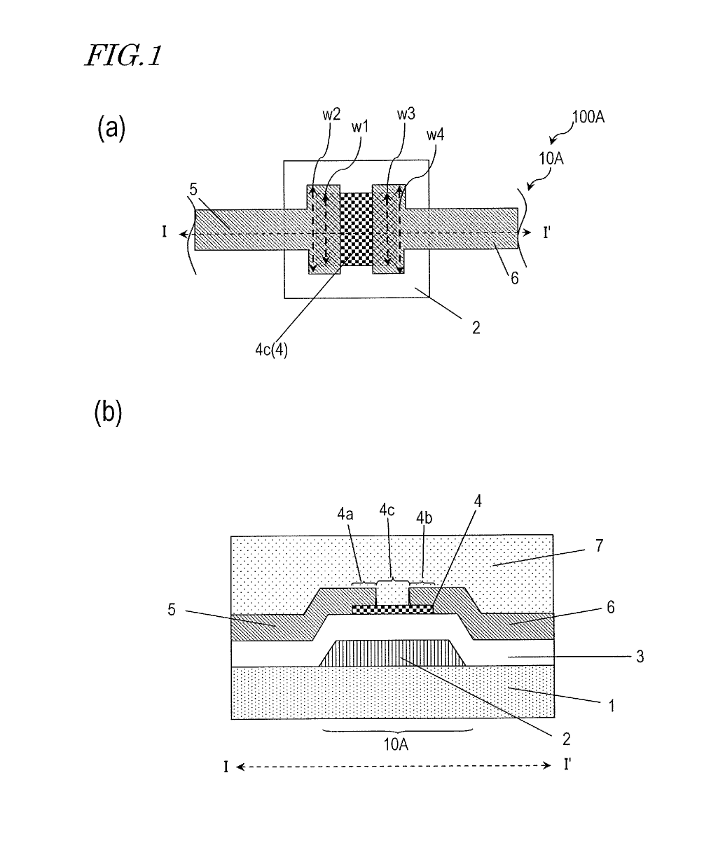

FIG. 1(a) is a schematic plan view of a semiconductor device 100A according to an embodiment of the present invention. FIG. 1(b) is a schematic cross-sectional view of a semiconductor device 100A along line I-I′ in FIG. 1 (a).

As shown in FIG. 1(a) and FIG. 1(b), the semiconductor device 100A includes a TFT 10A formed on a first substrate (e.g., a glass substrate) 1 and a protection layer 7 formed on the TFT 10A. The TFT 10A is an oxide semiconductor TFT, for example. The TFT 10A is a TFT for use in a pixel, for example. The TFT 10A includes a gate electrode 2, a gate insulating layer 3 formed on the gate electrode 2, an island-shaped oxide semiconductor layer 4 formed on the gate insulating layer 3, and a source electrode 5 and a drain electrode 6 formed on the oxide semiconductor layer 4. The oxide semiconductor layer 4 has a first contact region 4a, a second contact region 4b, and a channel region 4c located between the first contact region 4a and the second contact region 4b. The source electrode 5 is formed so as to be in contact with the first contact region 4a, whereas the drain electrode 6 is formed so as to be in contact with the second contact region 4b. All side faces of the oxide semiconductor layer 4 are located over the gate electrode 2. In a cross section which is perpendicular to the first substrate 1 and traverses the first contact region 4a in a channel width direction (i.e., a direction which is perpendicular to line I-I′ in FIG. 1(a)), the width w2 of the source electrode 5 is greater than the width w1 of the oxide semiconductor layer 4. Similarly, in a cross section which is perpendicular to the first substrate 1 and traverses the second contact region 4b in the channel width direction, the width w4 of the drain electrode 6 is greater than the width w3 of the oxide semiconductor layer 4. Moreover, within the surface of the oxide semiconductor layer 4, the first contact region 4a and the side faces of the first contact region 4a relative to the channel width direction are covered by the source electrode 5. Within the surface of the oxide semiconductor layer 4, the second contact region 4b and the side faces of the second contact region 4b relative to the channel width direction are covered by the drain electrode 6. Further said, within the surface of the oxide semiconductor layer 4, all upper face and side faces except the upper face of the channel region 4c and the side faces of the channel region 4c relative to the channel width direction are covered by the source electrode 5 or the drain electrode 6. Within the surface of the oxide semiconductor layer 4, the upper face of the channel region 4c and the side faces of the channel region 4c relative to the channel width direction are covered by an oxygen-containing insulative film (e.g., the protection layer 7), and are in contact with the oxygen-containing insulative film.

Thus, since all side faces of the oxide semiconductor layer 4 are located over the gate electrode 2, it is possible to block light which enters from the opposite side of the first substrate 1 from the TFT 10A and make it difficult for that light to strike the oxide semiconductor layer 4, without having to form a light shielding film as disclosed in Patent Document 4. Moreover, since regions other than the surface and side faces of the channel region 4c are covered by the source electrode 5 or the drain electrode 6, even if light entering from the TFT 10A side of the first substrate 1 undergoes diffuse reflection within a liquid crystal panel, for example, the light will be unlikely to strike the oxide semiconductor layer 4. Furthermore, unlike the semiconductor device disclosed in Patent Document 4, the semiconductor device 100A does not require a light shielding film to be formed; therefore, the semiconductor device 100A can be produced without increasing the number of production steps.

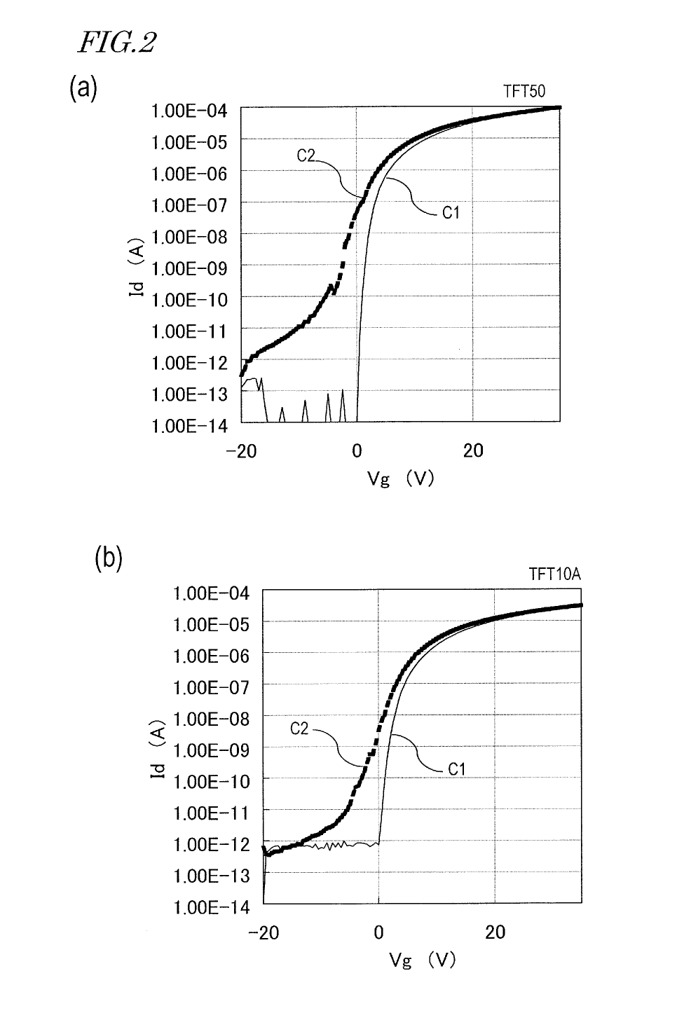

FIG. 2(a) is a graph showing a gate voltage (Vg)-drain current (Id) curve of an oxide semiconductor TFT (hereinafter referred to as the TFT 50) having the same construction as the TFT described in Patent Document 4, and FIG. 2(b) is a graph showing a gate voltage (Vg)-drain current (Id) curve of the TFT 10A. In the graphs of FIG. 2(a) and FIG. 2(b), curve C1 is a gate voltage (Vg)-drain current (Id) curve when each TFT is driven in a dark environment, whereas curve C2 is a gate voltage (Vg)-drain current (Id) curve when each TFT is driven in a bright environment (halogen light illuminance: 4 klx).

As shown in FIG. 2(a), with the TFT 50, when the TFT is driven in a bright environment, the OFF current is increased and the threshold voltage is shifted toward the lower voltage side as compared to when driving the TFT in a dark environment. As can be seen from FIG. 2(b), with the TFT 10A, even when the TFT is driven in a bright environment, the OFF current is not as much increased as in the TFT 50 and the threshold voltage is not much shifted toward the lower voltage side. In other words, the TFT 10A is structured so that light is unlikely to be radiated onto the oxide semiconductor layer 4 of the TFT 10A, and therefore its TFT characteristics are unlikely to change.

Thus, since the semiconductor device 100A is structured so that light is unlikely to strike the oxide semiconductor layer 4, an increase in the OFF current due to light is suppressed, and a shift of the threshold voltage toward the lower voltage side is also suppressed. Moreover, in the semiconductor device 100A, the oxide semiconductor layer 4 is shielded from light by using the gate electrode 2, the source electrode 5, and the drain electrode 6. Therefore, unlike in the semiconductor device disclosed in Patent Document 4, there is no need to separately provide a light shielding film, thus inducing no increase in the production cost.

The gate electrode 2, the source electrode 5, and the drain electrode 6 have a multilayer structure including an upper layer of an Al (aluminum) layer and a lower layer of a Ti (titanium) layer, for example. The upper layer may be a Cu (copper) layer, instead of an Al layer. Otherwise, the gate electrode 2, the source electrode 5, and the drain electrode 6 may have a single layer structure of a Ti, Mo (molybdenum), Ta (tantalum), or Cr (chromium) layer, for example. The thickness of the gate electrode 2, the source electrode 5, and the drain electrode 6 is not less than 100 nm and not more than 300 nm, for example.

Preferably, the gate insulating layer 3 and the protection layer 7 are made of an oxygen-containing insulative film. When the gate insulating layer 3 and the protection layer 7 are made of an oxygen-containing insulative film, oxygen will be supplied to the oxide semiconductor layer 4, so that oxygen defects in the oxide semiconductor layer 4 can be prevented. The gate insulating layer 3 and the protection layer 7 are made of SiO₂ (silicon dioxide), for example. Note that the gate insulating layer 3 and the protection layer 7 may be made of SiNₓ (silicon nitride). Alternatively, the gate insulating layer 3 and the protection layer 7 may be made of SiON (silicon oxynitride). Furthermore, the gate insulating layer 3 and the protection layer 7 may have a multilayer structure containing SiO₂, SiNₓ, or SiON. Moreover, a photosensitive organic insulative film may be formed on the protection layer 7. The thickness of the gate insulating layer 3 is not less than 300 nm and not more than 400 nm, for example. The thickness of the protection layer 7 is not less than 200 nm and not more than 300 nm, for example. Moreover, on the oxide semiconductor layer 4, an etch-stopper layer having contact holes for permitting electrical connection between the source electrode 5 and drain electrode 6 and the oxide semiconductor layer 4 may be formed. In this case, the etch-stopper layer is made of SiO₂, for example.

The oxide semiconductor layer 4 is an amorphous oxide semiconductor layer (a-IGZO layer) containing In (indium), Ga (gallium), and Zn (zinc), for example. The oxide semiconductor layer 4 may be an amorphous oxide semiconductor (a-IZO) layer containing In and Zn but not containing Ga, or an amorphous oxide semiconductor (a-ZnO) layer containing Zn but containing neither In nor Ga, for example. The thickness of the oxide semiconductor layer 4 is not less than 40 nm and not more than 60 nm, for example.

Next, semiconductor devices 100B and 100C according to other embodiments of the present invention, which provide the same effects as the semiconductor device 100A, will be described. Component elements which are common to the semiconductor device 100A will be denoted by like reference numerals, and any redundant description will be omitted.

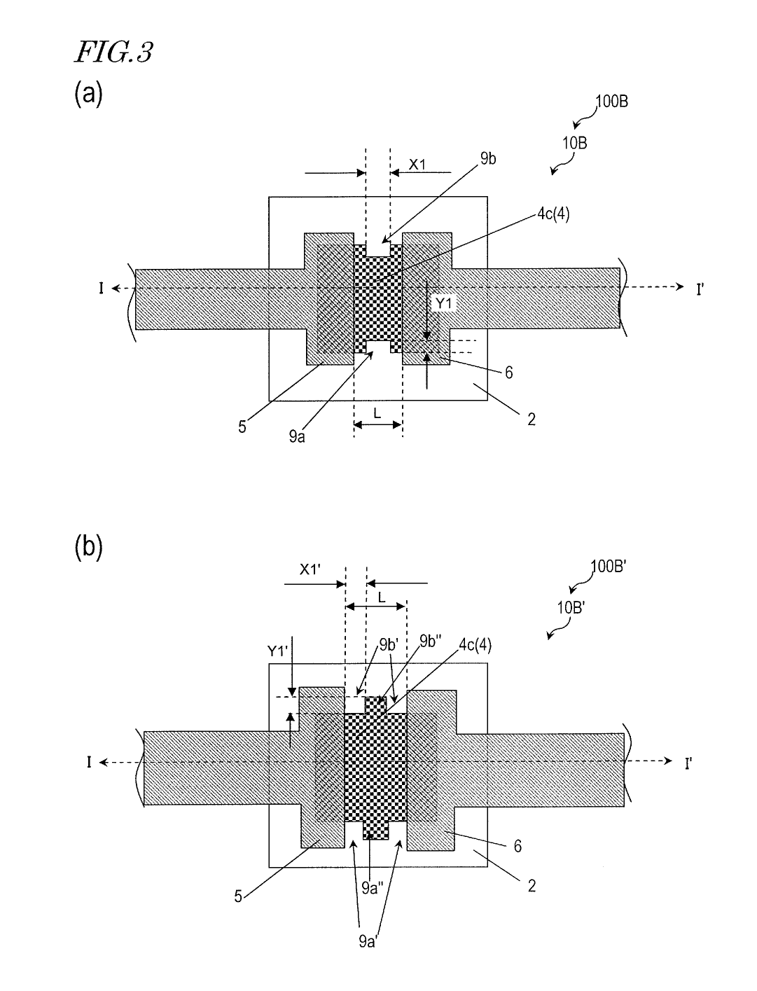

FIG. 3(a) is a schematic plan view of a TFT 10B included in the semiconductor device 100B. FIG. 3(b) is a schematic plan view of a TFT 10B′ included in a semiconductor device 100B′, which is a variant of the semiconductor device 100B. A cross-sectional view along line I-I′ in FIG. 3(a) and FIG. 3(b) would be identical to the cross-sectional view shown in FIG. 1(b).

As shown in FIG. 3(a), the oxide semiconductor layer 4 of the TFT 10B is structured so that, when viewed from the normal direction of the first substrate 1 (not shown), based on the oxide semiconductor layer 4 of the TFT 10A, recessed portions 9a and 9b are formed on side faces of the oxide semiconductor layer 4 in a portion not covered by the source electrode 5 and the drain electrode 6, the side faces being relative to a direction which is orthogonal to the channel direction (a direction perpendicular to line I-I′ in FIG. 1(a)). The TFT 10B is a TFT for use in a pixel, for example. Alternatively, only one of the recessed portions 9a and 9b may be formed. Moreover, it might be possible for the recessed portions 9a and 9b to be coincidentally (unintentionally) formed during the production process of the semiconductor device 100B.

Instead of forming the aforementioned recessed portions 9a and 9b, cutaway portions 9a′ and 9b′ may be formed as shown in FIG. 3(b). Specifically, the oxide semiconductor layer 4 of the TFT 10B′ is structured so that, when viewed from the normal direction of the first substrate (not shown), based on the oxide semiconductor layer 4 of the TFT 10A, cutaway portions 9a′ and 9b′ are formed in side faces of the oxide semiconductor layer 4 in a portion not covered by the source electrode 5 and the drain electrode 6, the side faces being relative to a direction which is orthogonal to the channel direction (a direction perpendicular to line I-I′ in FIG. 1(a)). Stated otherwise, the oxide semiconductor layer 4 of the TFT 10B′ includes, when viewed from the normal direction of the first substrate (not shown), based on the oxide semiconductor layer 4 of the TFT 10A, protrusion 9a″ and 9b″ on side faces of the oxide semiconductor layer 4 in a portion not covered by the source electrode 5 and the drain electrode 6, the side faces being relative to a direction which is orthogonal to the channel direction (a direction perpendicular to line I-I′). Note that, the cutaway portions 9a′ and 9b′ are formed between the protrusion 9a″ and 9b″ and the source electrode 5 or the drain electrode 6, respectively. Alternatively, only one of the cutaway portions 9a′ and 9b′ may be formed. Although two each of the cutaway portions 9a′ and 9b′ are formed in FIG. 3(b), there may be one cutaway portion 9a′ and one cutaway portion 9b′.

When viewed from the normal direction of the first substrate 1 (not shown), given a distance L between the source electrode 5 and the drain electrode 6 sandwiching the side faces of the channel region 4c, it is preferable that the length X1 or X1′ of the recessed portions 9a and 9b or the cutaway portions 9a′ and 9b′ along the channel length direction (i.e., a direction parallel to line I-I′ in FIGS. 3(a) and (b)) and the length Y1 or Y1′ of the recessed portions 9a and 9b or the cutaway portions 9a′ and 9b′ along the channel width direction (i.e., a direction perpendicular to line I-I′ in FIGS. 3(a) and (b)) are, each independently, greater than 0 but equal to or less than L/2.

By thus forming the recessed portions 9a and 9b or the cutaway portions 9a′ and 9b′, it becomes possible to reduce the area of light which enters from the TFT 10B or TFT 10B′ side of the first substrate 1 (not shown) and strikes the oxide semiconductor layer 4. As a result of this, changes in TFT characteristics due to light are less likely to occur than in the TFT 10A. Furthermore, since the area of contact between the oxide semiconductor layer 4 and the protection layer 7 is increased, the amount of oxygen supply from the oxygen-containing protection layer 7 to the oxide semiconductor layer 4 increases, for example, whereby oxygen defects in the oxide semiconductor layer 4 can be prevented. If the respective lengths X1, X1′, Y1, Y1′ of the recessed portions 9a and 9b and the cutaway portions 9a′ and 9b′ mentioned above become greater than L/2, the TFT characteristics may be deteriorated.

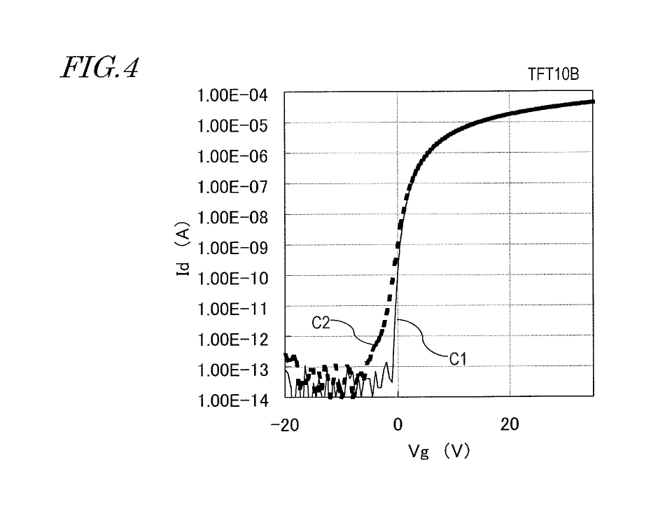

FIG. 4 is a graph showing a gate voltage (Vg)-drain current (Id) curve of the TFT 10B. In the graph of FIG. 4, curve C1 is a gate voltage (Vg)-drain current (Id) curve when the TFT 10B is driven in a dark environment, whereas curve C2 is a gate voltage (Vg)-drain current (Id) curve when the TFT 10B is driven in a bright environment (halogen light illuminance: 4 klx).

As can be seen from FIG. 4, similarly to the TFT 10A, the TFT 10B does not allow its OFF current to be increased or its threshold voltage to be shifted much toward the lower voltage side as compared to the TFT 50 (see FIG. 2(a)), even when the TFT is driven in a bright environment. Moreover, the TFT 10B having the recessed portions 9a and 9b formed therein incurs less increase in the OFF current and less shift of the threshold voltage toward the lower voltage side than does the TFT 10A (see FIG. 2(b)).

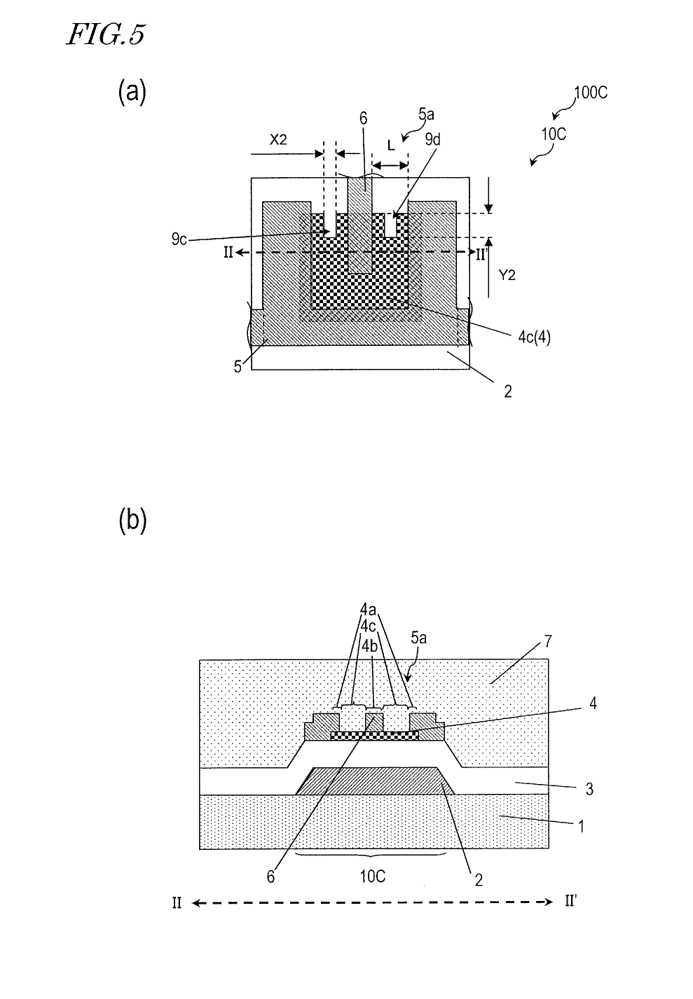

Next, a semiconductor device 100C according to still another embodiment of the present invention will be described with reference to FIG. 5.

FIG. 5(a) is a schematic plan view of the semiconductor device 100C. FIG. 5(b) is a schematic cross-sectional view of the semiconductor device 100C along line II-II′ in FIG. 5(a).

As shown in FIG. 5(a) and FIG. 5(b), the semiconductor device 100C includes a TFT 10C formed on a first substrate (e.g. a glass substrate) 1 and a protection layer 7 formed on the TFT 10C. The TFT 10C is an oxide semiconductor TFT, for example. The TFT 10C is a TFT for use in a pixel, for example. The TFT 10C includes a gate electrode 2, a gate insulating layer 3 formed on the gate electrode 2, an island-shaped oxide semiconductor layer 4 formed on the gate insulating layer 3, and a source electrode 5 and a drain electrode 6 formed on the oxide semiconductor layer 4. All side faces of the oxide semiconductor layer 4 are located over the gate electrode 2. The oxide semiconductor layer 4 has a first contact region 4a, a second contact region 4b, and a channel region 4c located between the first contact region 4a and the second contact region 4b. Moreover, when viewed from the normal direction of the first substrate 1, the source electrode 5 has a recessed portion 5a. The drain electrode 6 is partly within the recessed portion 5a. The recessed portion 5a of the source electrode 5 is formed so as to be in contact with the first contact region 4a, whereas the drain electrode 6 is formed so as to be in contact with the second contact region 4b. Since the source electrode 5 has the recessed portion 5a, the channel width can be increased. Regions of the oxide semiconductor layer 4 other than the surface and side faces of the channel region 4c are covered by the source electrode 5 and the drain electrode 6. Such a structure allows the area of the region of the oxide semiconductor layer 4 which is irradiated with light to be reduced.

Within the oxide semiconductor layer 4, recessed portions 9c and 9d are formed in a side face of the oxide semiconductor layer 4 in a region that is not covered by the recessed portion 5a of the source electrode 5 and the drain electrode 6. Alternatively, only one of the recessed portion 9c and recessed portion 9d may be formed. Moreover, it might be possible for the recessed portions 9c and 9d to be coincidentally (unintentionally) formed during the production process of the semiconductor device 100C.

When viewed from the normal direction of the first substrate 1 (not shown), given a distance L between the source electrode 5 and the drain electrode 6 sandwiching a side face of the channel region 4c, it is preferable that the length X2 of the recessed portions 9c and 9d along the channel length direction (i.e., a direction parallel to line II-II′) and the length Y2 of the recessed portions 9c and 9d along the channel width direction (i.e., a direction perpendicular to line II-II′) are, each independently, greater than 0 but equal to or less than L/2.

By thus forming the recessed portions 9c and 9d, it becomes possible to reduce the region in which light enters from the TFT 10C side of the first substrate 1 (not shown) and radiates the oxide semiconductor layer 4. As a result of this, changes in TFT characteristics due to light are less likely to occur than in any oxide semiconductor TFT in which the recessed portions 9c and 9d are not formed. Furthermore, since the area of contact between the oxide semiconductor layer 4 and the protection layer 7 is increased, the amount of oxygen supply from the oxygen-containing protection layer 7 to the oxide semiconductor layer 4 increases, for example, whereby oxygen defects in the oxide semiconductor layer 4 can be prevented. If the respective lengths X2, Y2 of the recessed portions 9c and 9d mentioned above become greater than L/2, the TFT characteristics may be deteriorated.

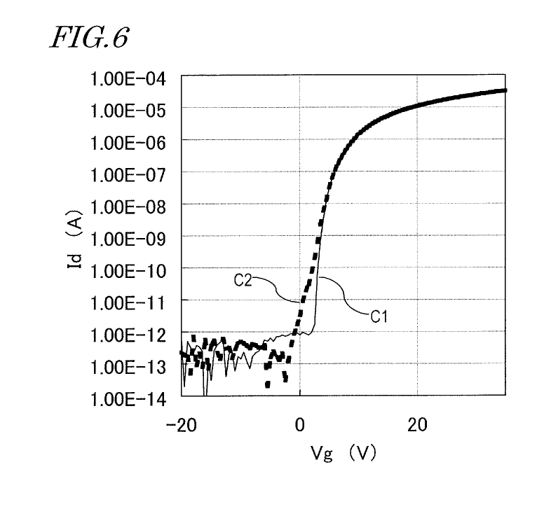

FIG. 6 is a graph showing a gate voltage (Vg)-drain current (Id) curve of the TFT 10C. In the graph of FIG. 6, curve C1 is a gate voltage (Vg)-drain current (Id) curve when the TFT 10C is driven in a dark environment, whereas curve C2 is a gate voltage (Vg)-drain current (Id) curve when the TFT 10C is driven in a bright environment (halogen light illuminance: 4 klx).

As can be seen from FIG. 6, similarly to the TFT 10A, TFT 10C does not allow its OFF current to be increased or its threshold voltage to be shifted much toward the lower voltage side as compared to the TFT 50, even when the TFT is driven in a bright environment. Moreover, similarly to the TFT 10B (see FIG. 4), the TFT 10C having the recessed portions 9c and 9d formed therein incurs little increase in the OFF current and little shift of the threshold voltage toward the lower voltage side.

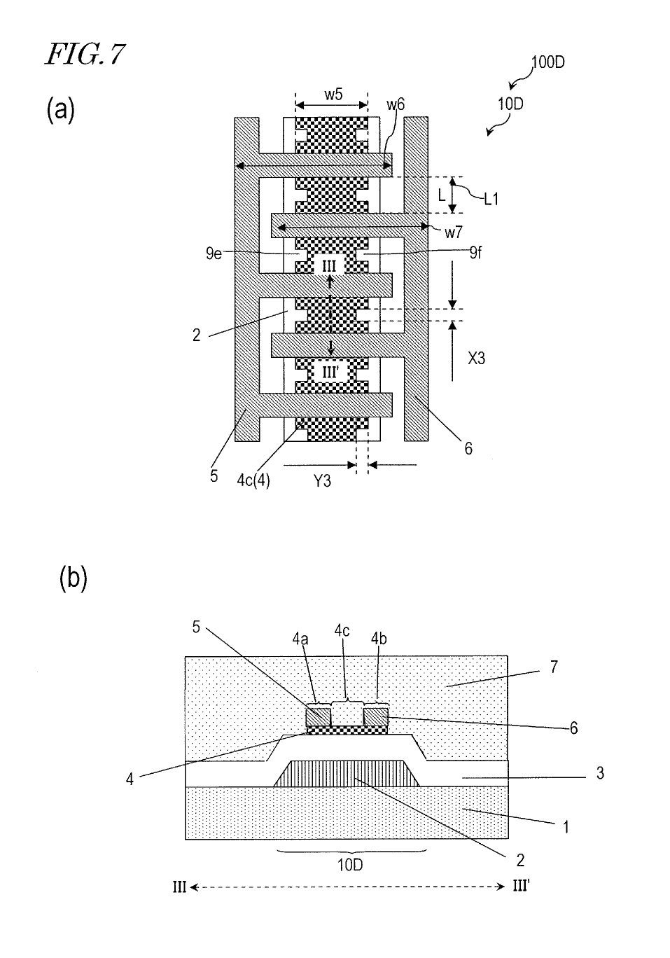

Next, a semiconductor device 100D according to still another embodiment of the present invention will be described with reference to FIG. 7.

FIG. 7(a) is a schematic plan view of the semiconductor device 100D. FIG. 7(b) is a schematic cross-sectional view of the semiconductor device 100D along line III-III′ in FIG. 7(a).

As shown in FIG. 7(a) and FIG. 7(b), the semiconductor device 100D includes a first substrate 1 (e.g., a glass substrate), a TFT 10D formed on the first substrate, and a protection layer 7 formed on the TFT 10D. The TFT 10D is an oxide semiconductor TFT, for example. The TFT 10D is a TFT for use in test wiring, which is to be used when conducting an electrical test of the semiconductor device 100D. Specifically, an electrical test of the semiconductor device 100D is conducted by placing test wiring in the outer periphery of the semiconductor device 100D, and turning ON/OFF an electrical signal used for the electrical test, by using a high voltage and a high current, for example. The TFT 10D is employed to switch ON/OFF this electrical signal. While the above-described TFTs 10A to 10C are to be formed in the displaying region, the TFT 10D for use in test wiring is to be formed in a peripheral region which is located around the displaying region, for example. The TFT 10D includes a gate electrode 2, a gate insulating layer 3 formed on the gate electrode 2, an island-shaped oxide semiconductor layer formed on the gate insulating layer 3, and a source electrode 5 and a drain electrode 6 formed on the oxide semiconductor layer 4. The oxide semiconductor layer 4 has first contact regions 4a, second contact regions 4b, and channel regions 4c located between the first contact regions 4a and the second contact regions 4b. There is a plurality of first contact regions 4a and second contact regions 4b. The source electrode 5 and drain electrode 6 have an interdigitated structure. The source electrode 5 is formed so as to be in contact with the first contact regions 4a, whereas the drain electrode 6 is formed so as to be in contact with the second contact regions 4b. All side faces of the oxide semiconductor layer 4 are located over the gate electrode 2. Thus, since all side faces of the oxide semiconductor layer 4 are located over the gate electrode 2, it is possible to block light which enters from the opposite side of the first substrate 1 from the TFT 10D and prevent that light from striking the oxide semiconductor layer 4, without having to form a light shielding film as disclosed in Patent Document 4.

In a cross section which is perpendicular to the first substrate 1 and traverses each first contact region 4a in the channel width direction (i.e., a direction perpendicular to line III-III′ in FIG. 7(a)), the width w6 of the source electrode 5 is greater than the width w5 of the oxide semiconductor layer 4. Similarly, in a cross section which is perpendicular to the first substrate 1 and traverses each second contact region 4b in the channel width direction, the width w7 of the drain electrode 6 is greater than the width w5 of the oxide semiconductor layer 4. Moreover, within the surface of the oxide semiconductor layer 4, each first contact region 4a and the side faces of each first contact region 4a relative to the channel width direction are covered by the source electrode 5. Within the surface of the oxide semiconductor layer 4, each second contact region 4b and the side faces of each second contact region 4b relative to the channel width direction are covered by the drain electrode 6. Further said, within the surface of the oxide semiconductor layer 4, all upper face and side faces except the upper face of each channel region 4c and the side faces of each channel region 4c relative to the channel width direction are covered by the source electrode 5 or the drain electrode 6. Within the surface of the oxide semiconductor layer 4, the upper face of each channel region 4c and the side faces of each channel region 4c relative to the channel width direction are covered by an oxygen-containing insulative film (e.g., the protection layer 7), and are in contact with the oxygen-containing insulative film.

When viewed from the normal direction of the first substrate 1, within the oxide semiconductor layer 4, recessed portions 9e and 9f are formed on side faces of the oxide semiconductor layer 4 in each portion not covered by the source electrode 5 and the drain electrode 6, the side faces being relative to a direction which is orthogonal to the channel direction (a direction perpendicular to line III-III′ in FIG. 7(a)). Alternatively, only one of the recessed portions 9e and 9f may be formed. Moreover, it might be possible for the recessed portions 9e and 9f to be coincidentally (unintentionally) formed during the production process of the semiconductor device 100D.

When viewed from the normal direction of the first substrate 1, given a distance L between the source electrode 5 and the drain electrode 6 sandwiching the side faces of each channel region 4c, it is preferable that the length X3 of the recessed portions 9e and 9f along the channel length direction (i.e., a direction parallel to line III-III′ in FIG. 7(a)) and the length Y3 of the recessed portions 9e and 9f along the channel width direction (i.e., a direction perpendicular to line III-III′ in FIG. 7(a)) are, each independently, greater than 0 but equal to or less than L/2.

By thus forming the recessed portions 9e and 9f, it becomes possible to reduce the area of light which enters from the TFT 10D of the first substrate 1 and strikes the oxide semiconductor layer 4. As a result of this, changes in TFT characteristics due to light are less likely to occur. Furthermore, since the area of contact between the oxide semiconductor layer 4 and the protection layer 7 is increased, the amount of oxygen supply from the oxygen-containing protection layer 7 to the oxide semiconductor layer 4 increases, for example, whereby oxygen defects in the oxide semiconductor layer 4 can be prevented. If the respective lengths X3, Y3 of the recessed portions 9e and 9f mentioned above become greater than L/2, the TFT characteristics may be deteriorated.

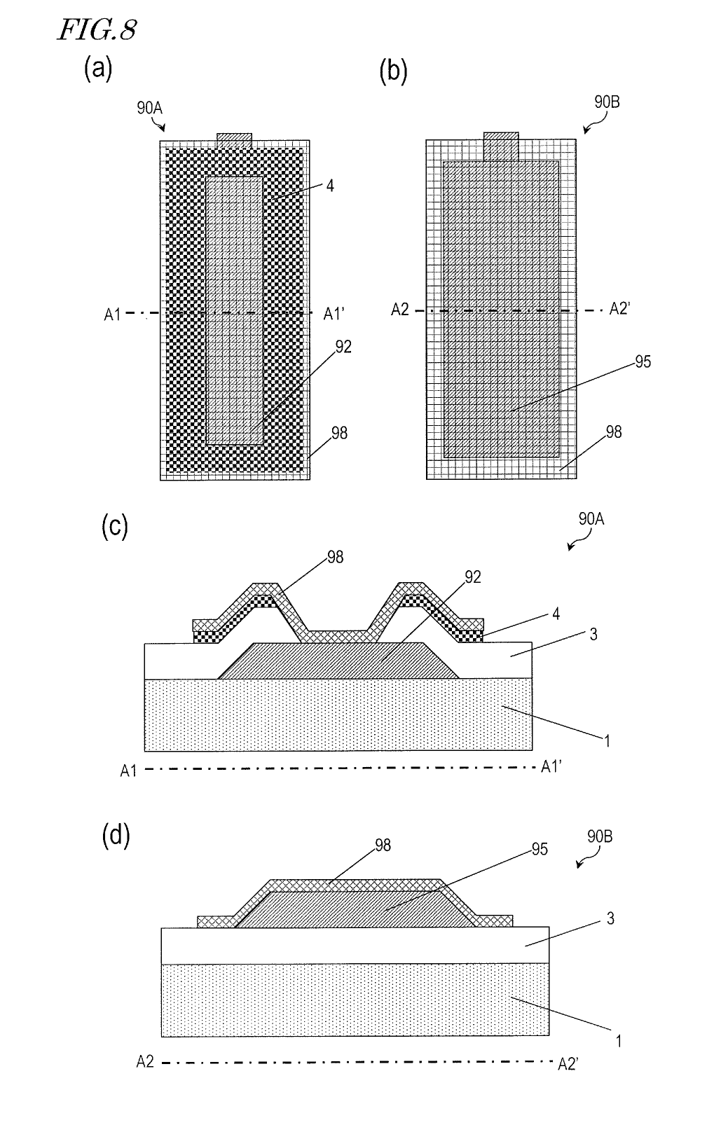

Next, terminals 90A and 90B included in the semiconductor devices 100A to 100D will be described with reference to FIG. 8.

FIG. 8(a) is a schematic plan view of the terminal 90A, and FIG. 8(b) is a schematic plan view of the terminal 90B. FIG. 8(c) is a schematic cross-sectional view of the terminal 90A, and FIG. 8(d) is a schematic cross-sectional view of the terminal 90B. The terminals 90A and 90B are terminals for connecting an external circuit to the semiconductor devices 100A to 100D, for example.

As shown in FIG. 8(a) and FIG. 8(c), the terminal 90A is formed on a first substrate 1. The terminal 90A includes a gate terminal portion 92 which is made of the same material as the gate electrode 2, a gate insulating layer 3 formed on the gate terminal portion 92, an island-shaped oxide semiconductor layer 4 formed on the gate insulating layer 3, and a pixel electrode portion 98 formed on the oxide semiconductor layer 4. The oxide semiconductor layer 4 is in contact with the pixel electrode portion 98. The pixel electrode portion 98 is electrically connected to the gate terminal portion 92 within a contact hole which is formed in the gate insulating layer 3.

As shown in FIG. 8(b) and FIG. 8(d), the terminal 90B is formed on a first substrate 1. The terminal 90B includes a source terminal portion 95 which is made of the same material as the source electrode 5, and a pixel electrode portion 98 formed on the source terminal portion 95. The source terminal portion 95 is electrically connected to the pixel electrode portion 98. The pixel electrode portion 98 is made of ITO (Indium Tin Oxide), for example.

Thus, according to embodiments of the present invention, there is provided a semiconductor device which can be produced without increasing the number of production steps and whose TFT characteristics are unlikely to be affected by light.

### INDUSTRIAL APPLICABILITY

The present invention has a very broad range of applications, and is applicable to semiconductor devices having TFTs, or electronic appliances in any field of art having such semiconductor devices. For example, it is applicable to active matrix-type liquid crystal display devices and organic EL display devices. For example, any such display device may be used as a display screen of a mobile phone or a portable game machine, a monitor of a digital camera, or the like. Thus, the present invention is applicable to any and all electronic appliances in which a liquid crystal display device or an organic EL display device is incorporated.

### REFERENCE SIGNS LIST

1 substrate
2 gate electrode
3 gate insulating layer
4 oxide semiconductor layer
4a first contact region
4b second contact region
4c channel region
5 source electrode
6 drain electrode
7 protection layer
10A TFT
100A semiconductor device
w1-w4 width

1-12. (canceled)

13. A semiconductor device comprising:
a substrate;
a gate electrode provided on the substrate;
a gate insulating layer provided on the gate electrode;
an island-shaped oxide semiconductor layer provided on the gate insulating layer, the oxide semiconductor layer including a first contact region and a second contact region and a channel region located between the first contact region and the second contact region;
a source electrode provided on the oxide semiconductor layer so as to be in contact with the first contact region; and
a drain electrode provided on the oxide semiconductor layer so as to be in contact with the second contact region, wherein,
all side faces of the oxide semiconductor layer are located over the gate electrode;
regions of the oxide semiconductor layer other than a surface and side faces of the channel region are covered by the source electrode and the drain electrode,
a region of the oxide semiconductor layer which is not covered by the source electrode or the drain electrode is covered by an oxygen-containing insulative film and is in contact with the oxygen-containing insulative film, and
when viewed from a normal direction of the substrate, a portion of the oxide semiconductor layer which is not covered by the source electrode and the drain electrode is provided with all of its portions directly between the source electrode and the drain electrode and includes a protrusion.

14. The semiconductor device of claim 13, wherein,
when viewed from a normal direction of the substrate, the portion of the oxide semiconductor layer which is not covered by the source electrode and the drain electrode has a first recessed portion or a first cutaway portion, and
when viewed from the normal direction of the substrate, given a distance L between the source electrode and the drain electrode sandwiching the side faces of the channel region, a length of the first recessed portion or the first cutaway portion along a channel length direction and a length of the first recessed portion or the first cutaway portion along the channel width direction are, each independently, greater than 0 but equal to or less than L/2.

15. The semiconductor device of claim 13, wherein the oxygen-containing insulative film is made of SiO₂.

16. The semiconductor device of claim 13, wherein, when viewed from a normal direction of the substrate, the source electrode has a recessed portion, and the drain electrode is within the recessed portion.

17. The semiconductor device of claim 13, wherein there is a plurality of first contact regions and second contact regions.

18. The semiconductor device of claim 13, wherein the oxide semiconductor layer contains In, Ga, and Zn
